(19) United States
(12) Patent Application Publication
(10) Pub. No.: US 2016/0071801 A1
(43) Pub. Date: Mar. 10, 2016

(54) SEMICONDUCTOR DEVICE ETCHING FOR RC DELAY IMPROVEMENT

(71) Applicant: TAIWAN SEMICONDUCTOR MANUFACTURING CO., LTD., Hsinchu (TW)

(72) Inventors: Jyh-nan LIN, Hsinchu City (TW); Mei-Ling CHEN, Kaohsiung City (TW); Fu-Chuen LIU, Zhubei City (TW)

(21) Appl. No.: 14/477,670

(22) Filed: Sep. 4, 2014

(51) Int. Cl. H01L 23/532; H01L 21/02; H01L 21/768; H01L 21/311; H01L 23/522; H01L 23/528

(52) U.S. Cl. CPC H01L 23/53238; H01L 23/5226; H01L 23/528; H01L 21/76802; H01L 21/76841; H01L 21/76877; H01L 21/31116; H01L 21/02167; H01L 21/0217; H01L 21/02175; H01L 21/02178

(57) ABSTRACT

In an etching method for fabricating a semiconductor device, at first, a semiconductor substrate including a contact region is provided. Then, a metallic nitride layer is formed on the semiconductor substrate to prevent over-etching. Thereafter, a dielectric layer is formed on the metallic nitride layer. Then, an etching process is performed to form an opening passing through the metallic nitride layer and the dielectric layer to expose the contact region. The etching method may further include forming a diffusion barrier layer between the metallic nitride layer and the semiconductor substrate to prevent diffusion of a material of the contact region.

### BACKGROUND

In general, various semiconductor devices such as resistors, transistors, and diodes are formed on or within a semiconductor substrate. These semiconductor devices are formed from conductor layers and dielectric layers. Etching processes are applied to expose a contact region of the conductor layers to electrically connect one semiconductor device to another. The conventional etching process generally needs an etch stop layer with a significant thickness to prevent over-etching. However, the etch stop layer results in high resistance-capacitance time delay (RC delay).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of a semiconductor device according to various embodiments.

FIG. 2A-FIG. 2G are schematic cross-sectional views of intermediate stages showing a method for forming a semiconductor device according to various embodiments.

FIG. 3 is a flow chart of a method for fabricating a semiconductor device in accordance with various embodiments.

FIG. 4 is a flow chart of a method for manufacturing a semiconductor device in accordance with various embodiments.

FIG. 5A-FIG. 5E are schematic cross-sectional views of intermediate stages showing a method for forming a semiconductor device according to various embodiments.

FIG. 6 is a flow chart of a method for fabricating a semiconductor device in accordance with various embodiments.

### DETAILED DESCRIPTION

The making and using of the present embodiments are discussed in detail below. It should be appreciated, however, that the present disclosure provides many applicable concepts that can be embodied in a wide variety of specific contexts. The specific embodiments discussed are merely illustrative of specific ways to make and use the disclosed subject matter, and do not limit the scope of the different embodiments. The present disclosure may repeat reference numerals and/or letters in the various examples. This repetition is for the purpose of simplicity and clarity and does not in itself dictate a relationship between the various embodiments and/or configurations discussed.

It will be understood that, although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

Reference throughout the specification to “one embodiment” or “an embodiment” means that a particular feature, structure, implementation, or characteristic described in connection with the embodiment is included in at least one embodiment of the present disclosure. Thus, uses of the phrases “in one embodiment” or “in an embodiment” in various places throughout the specification are not necessarily all referring to the same embodiment. Furthermore, the particular features, structures, implementation, or characteristics may be combined in any suitable manner in one or more embodiments.

Embodiments of the present disclosure are directed to providing an etching method for fabricating a semiconductor device. In the etching method, an etch stop layer is used to prevent over-etching. The etch stop layer includes a metallic nitride layer, and the etch stop layer can be formed with a relatively small thickness so as to decrease resistance-capacitance time delay (RC delay) of the semiconductor device. Compared with a conventional etching stop layer with a thickness of 250 Angstroms, the etch stop layer including the metallic nitride layer can be formed with a smaller thickness, such as 60 Angstroms. As a result, the semiconductor device using the etching stop layer including the metallic nitride layer has a relatively small resistance-capacitance time delay. In one embodiment, the etch stop layer has a multi-layer structure. The etch stop layer includes a metallic nitride layer and a diffusion barrier layer. The diffusion barrier layer is used to prevent diffusion of a conductor material disposed under the etch stop layer.

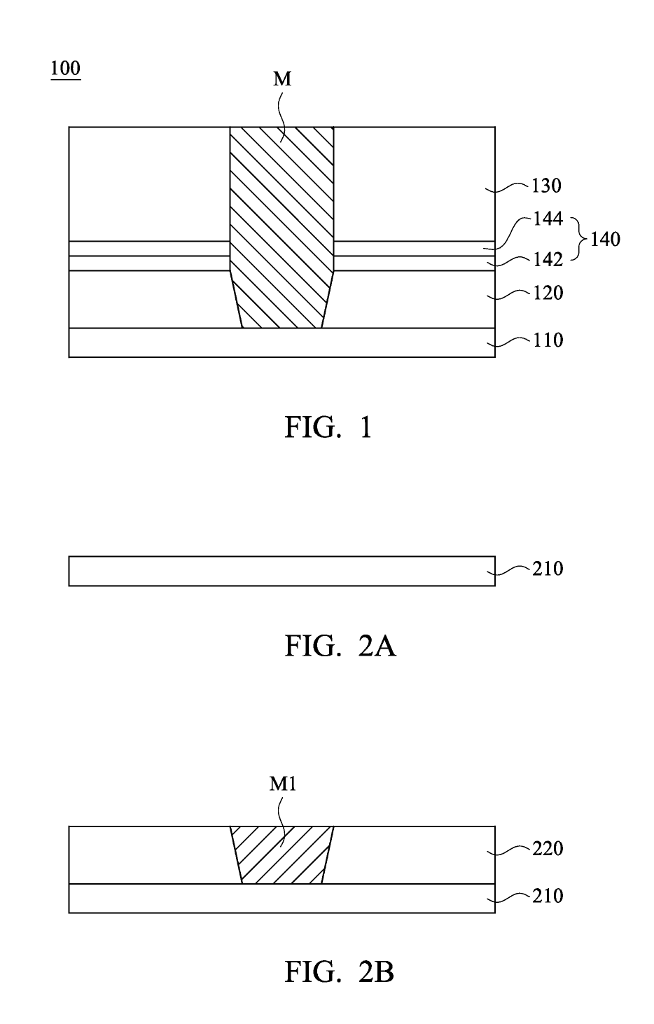

FIG. 1 is a schematic cross-sectional view of a semiconductor device 100 according to various embodiments. The semiconductor device 100 includes a semiconductor substrate 110, a first dielectric layer 120, a second dielectric layer 130, an etch stop layer 140 and a conductor M. The first dielectric layer 120 and the second dielectric layer 130 are formed on the semiconductor substrate 110. The etch stop layer 140 is formed between the first dielectric layer 120 and the second dielectric layer 130. The etch stop layer 140 has a multiple layer structure. The conductor M is used as a conductor line passing through the first dielectric layer 120, the second dielectric layer 130 and the etch stop layer 140.

The semiconductor substrate 110 is defined as any construction including semiconductor materials, including, but is not limited to, bulk silicon, a semiconductor wafer, a silicon-on-insulator (SOI) substrate, or a silicon germanium substrate. Other semiconductor materials including group III, group IV, and group V elements may also be used.

The first dielectric layer 120 and the second dielectric layer 130 include a dielectric material, such as silicon oxide, silicon nitride, silicon oxynitride, low-k dielectric material, other suitable dielectric materials, or combinations thereof. In some embodiments, the low-k dielectric materials include fluorinated silica glass (FSG), carbon doped silicon oxide, Black Diamond™ (Applied Materials of Santa Clara, Calif.), Xerogel, Aerogel, amorphous fluorinated carbon, Parylene, BCB (bis-benzocyclobutenes), SiLK (Dow Chemical, Midland, Mich.), polyimide, other proper materials, or combinations thereof. In some embodiments, the first dielectric layer 120 and the second dielectric layer 130 include a multilayer structure having multiple dielectric materials.

The conductor M is a conductor line for transmitting signals and includes a conductive material, such as aluminum (Al), copper (Cu), silver (Ag), gold (Au), nickel (Ni), tungsten (W), or an alloy thereof.

The etch stop layer 140 includes a diffusion barrier layer 142 and a metallic nitride layer 144. The diffusion barrier layer 142 is used to prevent diffusion of the material of the conductor M when the semiconductor device 100 is fabricated. The metallic nitride layer 144 is used to prevent over-etching when an etching process is performed for fabricating the semiconductor device 100. The metallic nitride layer 144 is formed with a group III metal nitride material, such as GaN or AN. The material forming the diffusion barrier layer 142 is selected in accordance with the material of the conductor M. In some embodiments, the diffusion barrier layer 142 is formed from a silicon carbon based material, such as SiCN, SiCO or SiCON.

The etch stop layer 140 can be formed with a relatively small thickness so as to decrease resistance-capacitance time delay of the semiconductor device 100. In one embodiment, the thickness of the diffusion barrier layer 142 ranges from 30 Angstroms to 60 Angstroms, and the thickness of the metallic nitride layer 144 ranges from 5 Angstroms to 15 Angstroms. In some embodiments, the thickness of the diffusion barrier layer 142 is 50 Angstroms, and the thickness of the metallic nitride layer 144 is 10 Angstroms.

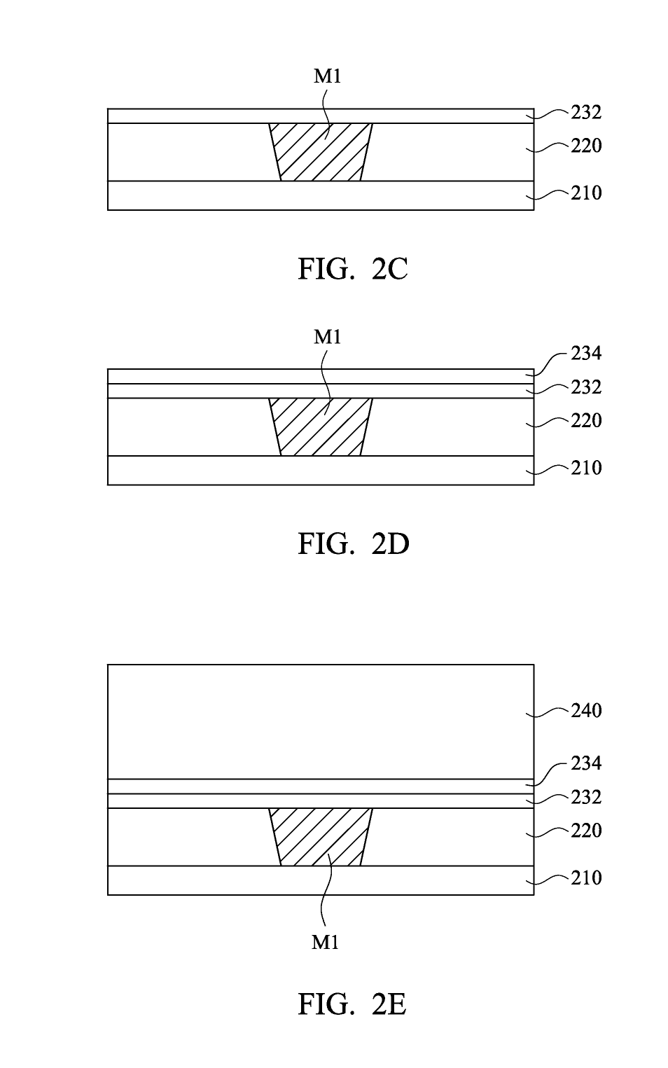

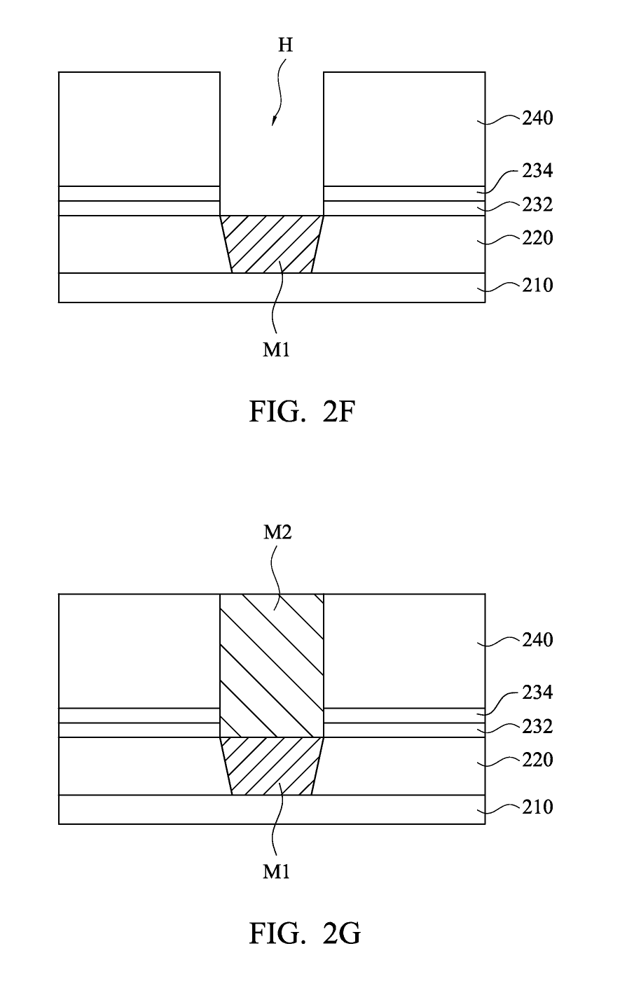

Referring to FIG. 2A-FIG. 2G, FIG. 2A-FIG. 2G are schematic cross-sectional views of intermediate stages showing a method for forming a semiconductor device according to various embodiments. As shown in FIG. 2A, a semiconductor substrate 210 is provided. As shown in FIG. 2B, a first dielectric layer 220 and a first conductor M1 are formed on the semiconductor substrate 210. The first dielectric layer 220 has a first opening, and the first conductor M1 is located in the first opening. In this embodiment, the first dielectric layer 220 is formed from a low-k material, and the first conductor M1 is formed from copper.

As shown in FIG. 2C, a diffusion barrier layer 232 is formed on the first dielectric layer 220 and the first conductor M1 to prevent diffusion of the material of the first conductor M1. In this embodiment, the diffusion barrier layer 232 is formed from SiCN, and a thickness thereof is 50 Angstroms. As shown in FIG. 2D, a metallic nitride layer 234 is formed on the diffusion barrier layer 232 to prevent over-etching. In this embodiment, the metallic nitride layer 234 is formed from GaN or AlN.

As shown in FIG. 2E, a second dielectric layer 240 is formed on the metallic nitride layer 234. In this embodiment, the second dielectric layer 240 is formed from a low-k material. As shown in FIG. 2F, an etching process is performed to form a second opening H passing through the diffusion barrier layer 232, the metallic nitride layer 234 and the second dielectric layer 240 to expose the first conductor M1. In this embodiment, the etching process is a dry etching process. As shown in 2G, a second conductor M2 is formed in the second opening to contact with the first conductor M1. In this embodiment, the second conductor M2 is formed from copper.

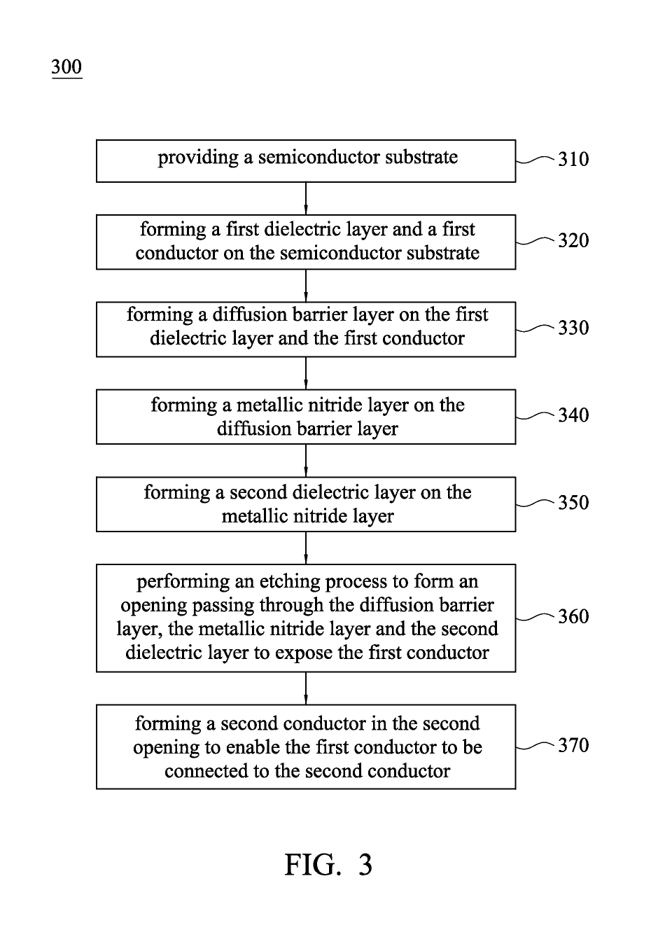

Referring to FIG. 3 with FIG. 2A-FIG. 2H, FIG. 3 is a flow chart of a method 300 for fabricating a semiconductor device in accordance with various embodiments. The method 300 begins at operation 310, where the semiconductor substrate 210 is provided, as shown in FIG. 2A. At operation 320, the first dielectric layer 220 and the first conductor M1 are formed on the semiconductor substrate 210, as shown in FIG. 2B. In operation 320, the first dielectric layer 220 and the first conductor M1 are formed by using deposition processes including but not limited to a chemical vapor deposition (CVD) process or a physical vapor deposition (PVD) process.

At operation 330, the diffusion barrier layer 232 is formed on the first dielectric layer 220 and the first conductor M1 to prevent diffusion of the material of the first conductor M1, as shown in FIG. 2C. In operation 330, the diffusion barrier layer 232 is formed by using a deposition process, such as a CVD process, a plasma enhanced chemical vapor deposition (PECVD) process, or an atomic layer chemical vapor deposition (ALCVD) process. At operation 340, the metallic nitride layer 234 is formed on the diffusion barrier layer 232 to prevent over-etching, as shown in FIG. 2D. In operation 340, the metallic nitride layer 234 is formed by using a deposition process, such as a CVD process, a PECVD process, or an ALCVD process.

At operation 350, the second dielectric layer 240 is formed on the metallic nitride layer 234, as shown in FIG. 2E. In operation 350, the second dielectric layer 240 is formed by using a deposition process such as a CVD process or a PVD process. At operation 360, an etching process is performed to form the second opening passing through the diffusion barrier layer 232, the metallic nitride layer 234 and the second dielectric layer 240 to expose the first conductor M1, as shown in FIG. 2F. In operation 360, the second opening is formed by using a dry etching process. In operation 360, the second opening is formed by using a dry etching process. At operation 370, the second conductor M2 is formed in the second opening to contact with the first conductor M1, as shown in FIG. 2G. In this embodiment, the second conductor M2 is formed by using a deposition process, such as a CVD process or a PVD process.

Comparing with the conventional material forming a conventional etch stop layer, the etch stop layer formed from metallic nitride in the embodiments of the present disclosure can be formed with a relatively small thickness, thereby decreasing RC delay of the semiconductor device.

It is noted that the diffusion barrier layer used in the embodiments can be saved when a diffusion coefficient of the material of the first conductor M1 is acceptable.

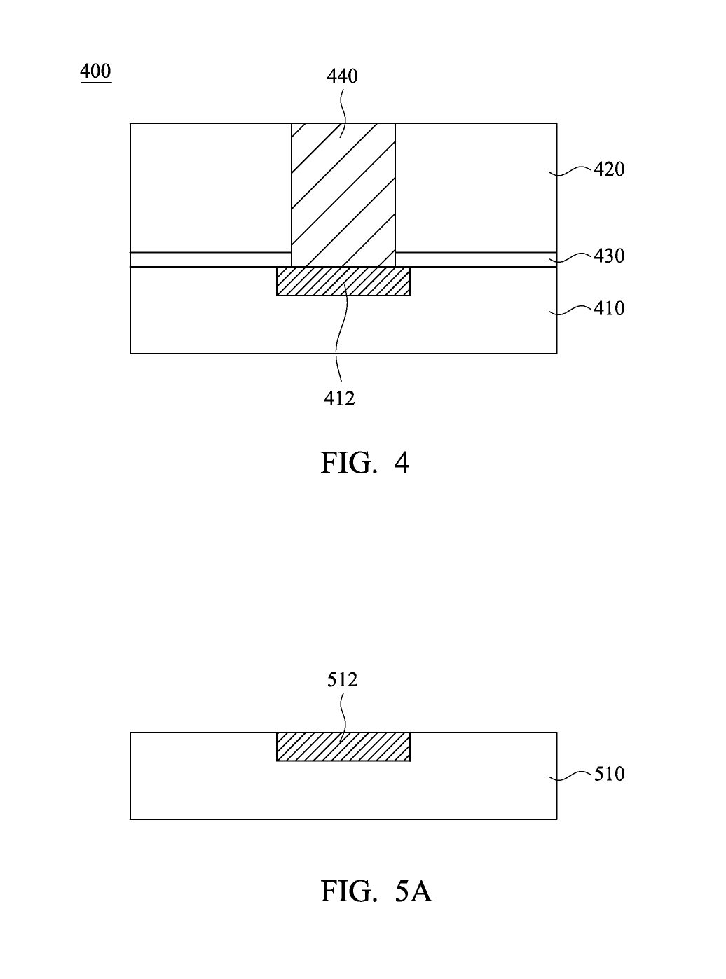

FIG. 4 is a schematic cross-sectional view of a semiconductor device 400 according to various embodiments. The semiconductor device 400 includes a semiconductor substrate 410, a dielectric layer 420, an etch stop layer 430 and a conductor 440. In some embodiments, the semiconductor substrate 410 has a semiconductor element formed therein, and a contact region 412 of the semiconductor element is exposed on a surface of the semiconductor substrate 410. In one embodiment, the semiconductor element is a Metal-Oxide-Semiconductor Field-Effect Transistor (MOSFET) and a source/drain of the MOSFET is exposed to be the contact region 412.

The dielectric layer 420 is formed on the semiconductor substrate 410, and the etch stop layer 430 is formed between the dielectric layer 420 and the semiconductor substrate 410. In this embodiment, the etch stop layer 430 includes a metallic nitride layer 432 to prevent over-etching. The conductor 440 is used as a conductor line passing through the dielectric layer 420 and the etch stop layer 430 to contact with the contact region 412 of the semiconductor substrate 410.

In this embodiment, the etch stop layer 430 does not include a diffusion barrier layer, and thus a thickness of the etch stop layer 430 can be further decreased. Comparing with the semiconductor device 100, the semiconductor device 400 has a relatively small resistance-capacitance time (RC) delay because the etch stop layer 430 has a relatively small thickness. In one embodiment, a thickness of the etch stop layer 430 ranges from 5 Angstroms to 15 Angstroms.

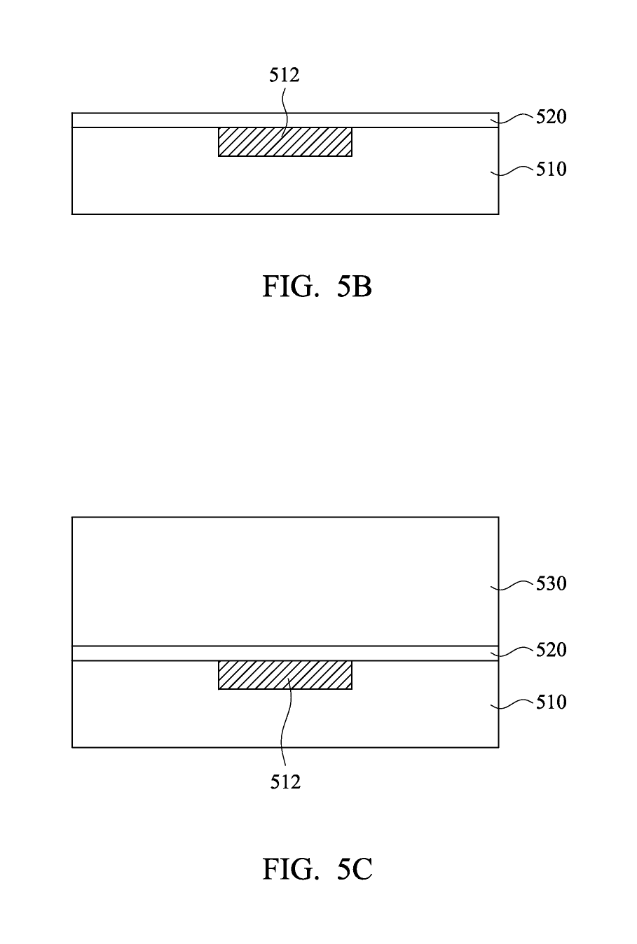

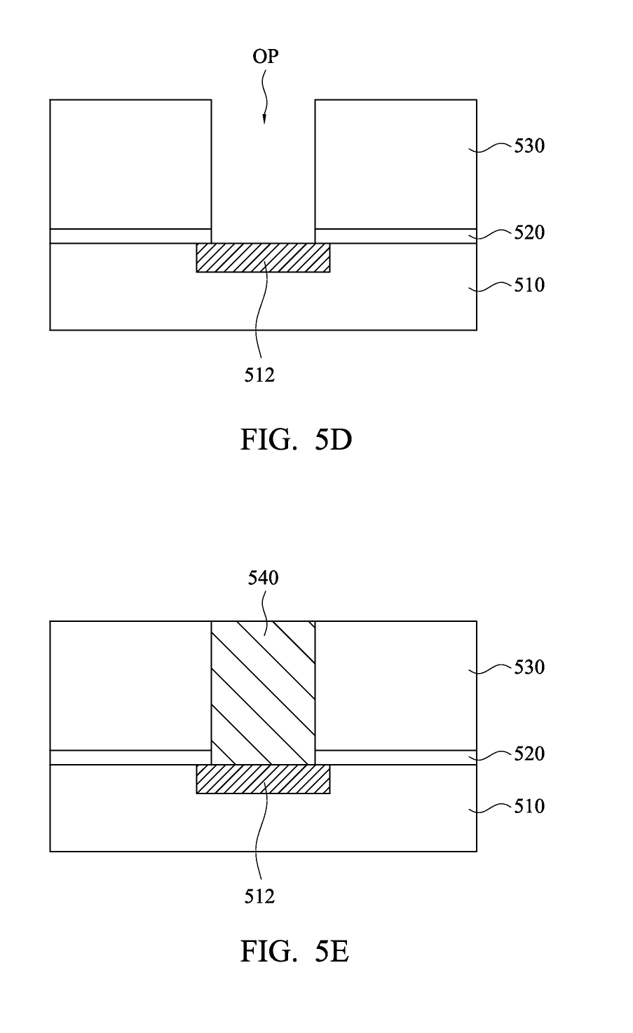

Referring to FIG. 5A-FIG. 5E, FIG. 5A-FIG. 5E are schematic cross-sectional views of intermediate stages showing a method for forming a semiconductor device according to various embodiments. As shown in FIG. 5A, a semiconductor substrate 510 is provided. The semiconductor substrate 510 has a semiconductor element formed therein, and a contact region 512 of the semiconductor element is exposed on a surface of the semiconductor substrate 510. In one embodiment, the semiconductor element is a MOSFET and a source/drain of the MOSFET is exposed to be the contact region 512. In one embodiment, a diffusion coefficient of the material of the contact region 512 is acceptable.

As shown in FIG. 5B, a metallic nitride layer 520 is formed on the semiconductor substrate 510 to prevent over-etching. In this embodiment, the metallic nitride layer 520 is formed from GaN or AN. As shown in FIG. 5C, a dielectric layer 530 is formed on the metallic nitride layer 520. In this embodiment, the dielectric layer 530 is formed from a low-k material. As shown in FIG. 5D, an etching process is performed to form an opening OP passing through the metallic nitride layer 520 and the dielectric layer 530 to expose the contact region 512. In this embodiment, the etching process is a dry etching process. As shown in 5E, a conductor 540 is formed in the opening OP to contact with the contact region 512 of the semiconductor substrate 510. In this embodiment, the conductor 540 is formed from copper.

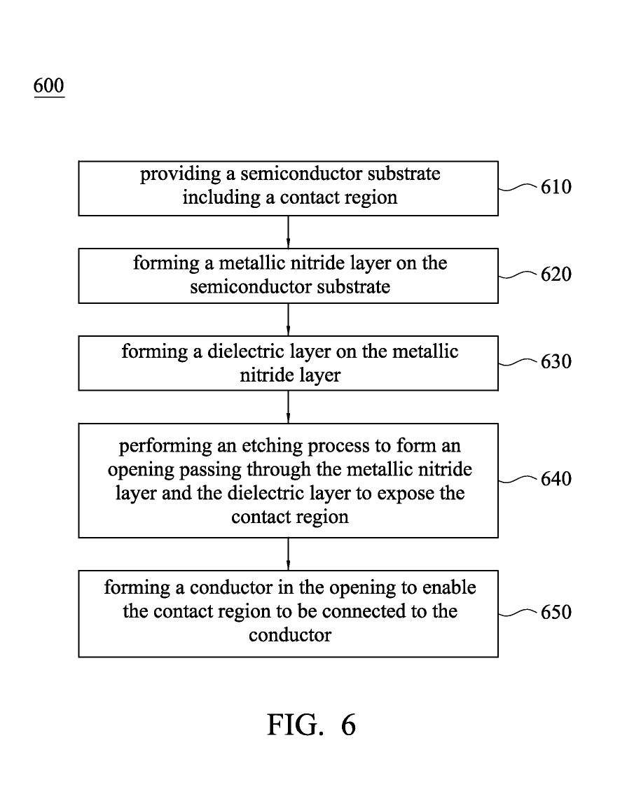

Referring to FIG. 6 with FIG. 5A-FIG. 5E, FIG. 6 is a flow chart of a method 600 for fabricating a semiconductor device in accordance with various embodiments. The method 600 begins at operation 610, where the semiconductor substrate 510 is provided, as shown in FIG. 5A. At operation 620, the metallic nitride layer 520 is formed on the semiconductor substrate 510 to prevent over-etching, as shown in FIG. 5B. In operation 620, the metallic nitride layer 520 is formed by using a deposition process, such as a CVD process, a PECVD process, or an ALCVD process. In one embodiment, a thickness of the metallic nitride layer 520 ranges from 5 Angstroms to 15 Angstroms.

At operation 630, the dielectric layer 530 is formed on the metallic nitride layer 520, as shown in FIG. 5C. In operation 630, the dielectric layer 530 is formed by using a deposition process, such as a CVD process or a PVD process. At operation 640, an etching process is performed to form the opening OP passing through the metallic nitride layer 520 and the dielectric layer 530 to expose the contact region 512, as shown in FIG. 5D. In operation 640, the opening is formed by using a dry etching process. At operation 650, the conductor 540 is formed in the opening OP to contact with the contact region 512 of the semiconductor substrate 510, as shown in FIG. 5E. In this embodiment, the conductor 540 is formed by using a deposition process, such as a CVD process or a PVD process.

In accordance with some embodiments, the present disclosure discloses an etching method. In the etching method, at first, a semiconductor substrate including a contact region is provided. Then, a metallic nitride layer is formed on the semiconductor substrate. Thereafter, a dielectric layer is formed on the metallic nitride layer. Then, an etching process is performed to form an opening passing through the dielectric layer and the metallic nitride layer to expose the contact region.

In accordance with certain embodiments, the present disclosure discloses a semiconductor device including a semiconductor substrate, a first dielectric layer, a second dielectric layer, an etch stop layer and a conductor. The first dielectric layer is formed on the semiconductor substrate, in which the first dielectric layer has a first opening. The second dielectric layer is formed on the first dielectric layer, in which the second dielectric layer has a second opening. The etch stop layer is formed between the first dielectric layer and the second dielectric layer, in which the etch stop layer has a third opening connecting the first opening to the second opening, and includes a metallic nitride layer. The conductor is formed in the first opening, the second opening and the third opening.

In accordance with certain embodiments, the present disclosure discloses a method for fabricating a semiconductor device. In the method, at first, a semiconductor substrate is provided. Then, a first dielectric layer and a first conductor are formed on the semiconductor substrate, in which the first dielectric layer has a first opening, and the first conductor is located in the first opening. Thereafter, a metallic nitride layer is formed on the first dielectric layer and the first conductor. Then, a second dielectric layer is formed on the metallic nitride layer. Thereafter, an etching process is performed to form a second opening passing through the diffusion barrier layer, the metallic nitride layer and the second dielectric layer to expose the first conductor. Then, a second conductor is formed in the second opening to enable the first conductor to be connected to the second conductor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An etching method, the method comprising:
providing a semiconductor substrate comprising a contact region;
forming a metallic nitride layer on the semiconductor substrate;
forming a dielectric layer on the metallic nitride layer; and
performing an etching process to form an opening passing through the dielectric layer and the metallic nitride layer to expose the contact region.

2. The etching method of claim 1, further comprising forming a diffusion barrier layer between the semiconductor substrate and the metallic nitride layer, wherein the opening is formed through the diffusion barrier layer.

3. The etching method of claim 2, wherein a material forming the contact region is copper and a material forming the diffusion barrier layer is SiCN.

4. The etching method of claim 2, wherein the diffusion barrier layer has a thickness ranging from 30 Angstroms to 60 Angstroms.

5. The etching method of claim 1, wherein a metal of the metallic nitride layer is a group III metal.

6. The etching method of claim 5, wherein the metallic nitride layer is formed from GaN or AlN.

7. The etching method of claim 1, wherein the etching process is a dry etching process.

8. The etching method of claim 1, wherein the metallic nitride layer has a thickness ranging from 5 Angstroms to 15 Angstroms.

9-16. (canceled)

17. A method for fabricating a semiconductor device, the method comprising:
providing a semiconductor substrate;
forming a first dielectric layer and a first conductor on the semiconductor substrate, wherein the first dielectric layer has a first opening, and the first conductor is located in the first opening;
forming a metallic nitride layer on the first dielectric layer and the first conductor;
forming a second dielectric layer on the metallic nitride layer;
performing an etching process to form a second opening passing through the metallic nitride layer and the second dielectric layer to expose the first conductor; and
forming a second conductor in the second opening to connect the first conductor to the second conductor.

18. The method of claim 17, further comprising forming a diffusion barrier layer between the metallic nitride layer and the first dielectric layer.

19. The method of claim 17, wherein a material forming the metallic nitride layer is a group III metal nitride.

20. The method of claim 17, wherein the etching process is a dry etching process.

21. The etching method of claim 1, wherein the contact region is a source of a Metal-Oxide-Semiconductor Field-Effect Transistor.

22. The etching method of claim 1, wherein the contact region is a drain of a Metal-Oxide-Semiconductor Field-Effect Transistor.

23. The method of claim 18, wherein a material forming the diffusion barrier layer is SiCN.

24. The method of claim 18, wherein the diffusion barrier layer has a thickness ranging from 30 Angstroms to 60 Angstroms.

25. The method of claim 19, wherein the metallic nitride layer is formed from GaN or AlN.

26. The method of claim 17, wherein the metallic nitride layer has a thickness ranging from 5 Angstroms to 15 Angstroms.

27. The method of claim 17, wherein the first conductor is formed from copper.

28. The method of claim 17, wherein the second conductor is formed from copper.
